(19) United States
(12) Patent Application Publication
(10) Pub. No.: US 2005/0117294 A1
(43) Pub. Date: Jun. 2, 2005

(54) Heat sink device of computer case

(75) Inventor: Wei-Jia Hsieh, TAIPEI (TW)

Correspondence Address: SOLTEK COMPUTERS INC., F-4, NO 148, SEC. 4 CHUNG-HSIAO E. ROAD, TAIPEI, TW

(73) Assignee: SOLTEK COMPUTER INC., TAIPEI (TW)

(21) Appl. No.: 10/709,073

(22) Filed: Apr. 12, 2004

(30) Foreign Application Priority Data
Nov. 28, 2003 (TW) 092133524

(51) Int. Cl. H05K 5/00

(52) U.S. Cl. 361/695

(57) ABSTRACT

A heat sink device in a computer case is provided. The computer case comprises at least a plurality of ventilation holes and a plurality of exhaust holes formed on a sidewall thereof. At least a motherboard and a power supplier are installed within the computer case. The heat sink device comprises a scroll fan, installed inside the computer case below the power supplier. The scroll fan comprises an air inlet at a distal end and an air outlet at a primal end thereof. The air outlet is connected to the ventilation holes of the computer case. The scroll fan is adapted for generating air and circulating air within the computer case, and dissipating heat from inside the computer case.

### CROSS REFERENCE TO RELATED APPLICATIONS

This application claims the priority benefit of Taiwan patent appliction number 092133524 filed on Nov. 28, 2003.

### BACKGROUND OF INVENTION

The present invention generally relates to a heat sink device of a computer case, and more particularly to a heat sink device comprising a scroll fan for effectively absorbing and exhausting the heat from inside the computer to outside atmosphere.

Generally, a computer comprises a motherboard, a power supplier, various electronic components, a CPU and so on, installed inside the computer case. Operation of some of these components, for example, the power supplier, the various electronic components and the CPU generate heat. If the heat generated is not removed and remain within the computer case, the heat would adversely impact the performance of the electronic components and the service life of the electronic components will be shortened. Thus, the computer breaks down. Accordingly, it is important to remove the heat from within the computer case. Conventionally, heat exchange plates and a fan, which is axially positioned, are utilized for removing the heat from the computer case, whereby the heat is suck out by the fan installed on the inner sidewall of the computer case. However, the suction of the air by the conventional fan is substantially axial, therefore the speed of heat dissipation is limited, and the poor air circulation inside the computer case further limits the heat dissipation. Accordingly, the conventional heat sink device including the heat exchange plate and the fan has the following defects.

1. The fan is small and is not efficient to provide desirable heat exchange, thus the heat generated by the electronic components installed within the computer case cannot be removed efficiently and poor air circulation within the computer case allows heat retention which would adversely affect the performance of the electronic components.

2. Because the fan installed on the sidewall is utilized to suck the air from inside the computer case, and therefore the heat dissipation speed is substantially slower than the speed at which the heat being generated by the electronic components. Therefore, the heat dissipation via the conventional fan arrangement is limited.

3. The ventilation holes on the sidewall of the computer case are small and formed close to each other, thus the outside air cannot easily get inside the computer case. Therefore, the hot air within the computer case cannot be efficiently removed.

4. The fan is utilized for only sucking the air out from inside the computer case and does not aid in air circulation within the computer case and thus limiting the heat dissipation.

The convention axial fan for heat exchange in the computer case has less heat exchange effect, and the defects thereof are the priority for the manufactures in the field to overcome.

### SUMMARY OF INVENTION

Accordingly, in the view of the foregoing, the present inventor makes a detailed study of related art to evaluate and consider, and uses years of accumulated experience in this field, and through several experiments, to create a new heat sink device for a computer case. The present invention provides an innovated cost effective and efficient heat sink device capable of efficiently dissipating heat from within the computer case to outside so that the service life of the electronic components installed within the computer case can be effectively extended.

According to an aspect of the present invention, a scroll fan is installed under the power supplier vertically positioned relative to the motherboard inside the computer case. The air generated by the operation of the scroll fan provides a better air circulation effect and larger area so that the heat generated by the operation of the electronic components within the computer case can be efficiently and effectively dissipated out of the computer case.

According to another aspect of the present invention, the mass heat absorbance effect provided by the operation of the scroll fan can effectively promote the speed of heat dissipation from the computer case.

According to another aspect of the present invention, the scroll fan is installed vertical relative to the motherboard, therefore the air generated by the operation of the scroll fan is capable of circulating air on the motherboard to effectively remove the heat from the motherboard and dissipate the heat out of the computer case.

### BRIEF DESCRIPTION OF DRAWINGS

For a more complete understanding of the present invention, reference will now be made to the following detailed description of preferred embodiments taken in conjunction with the following accompanying drawings.

FIG. 1 is an elevational view of a computer case comprising a heat sink device according to an embodiment of the present invention.

FIG. 2 is an elevational view of the computer case comprising a heat sink device shown in FIG. 1 when viewed from another direction.

FIG. 3 is a side view of the computer case comprising a heat sink device shown in FIG. 1.

FIG. 4 is a view showing an operation of the scroll fan according to an embodiment of the present invention.

### DETAILED DESCRIPTION

Reference will be made in detail to the preferred embodiments of the invention, examples of which are illustrated in the accompanying drawings. Wherever possible, the same reference numbers are used in the drawings and the description to refer to the same or like parts.

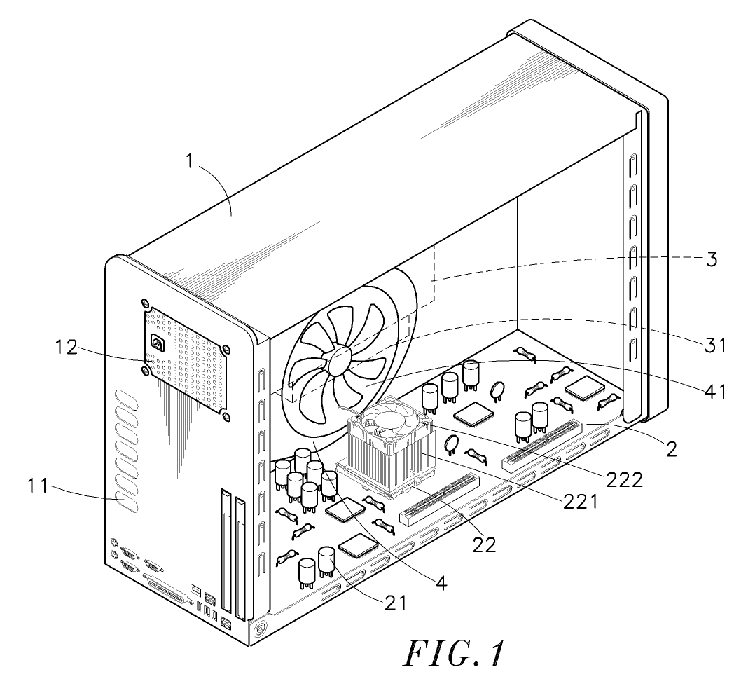

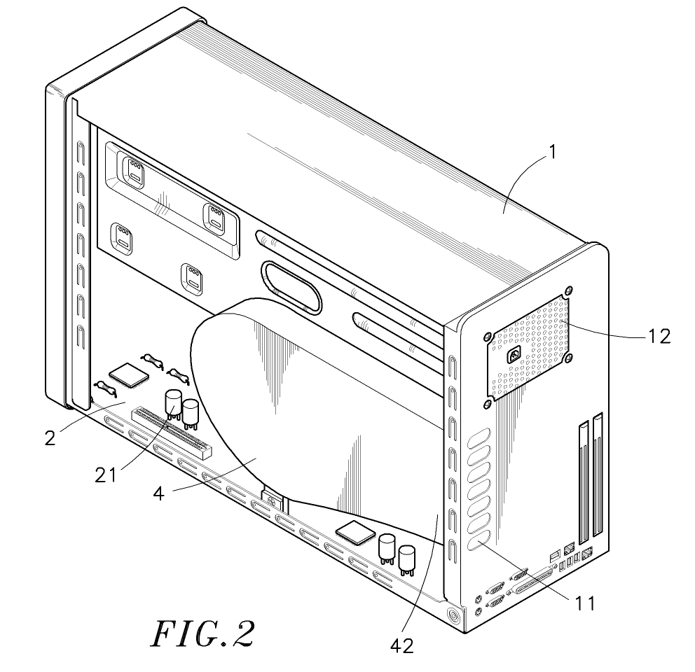

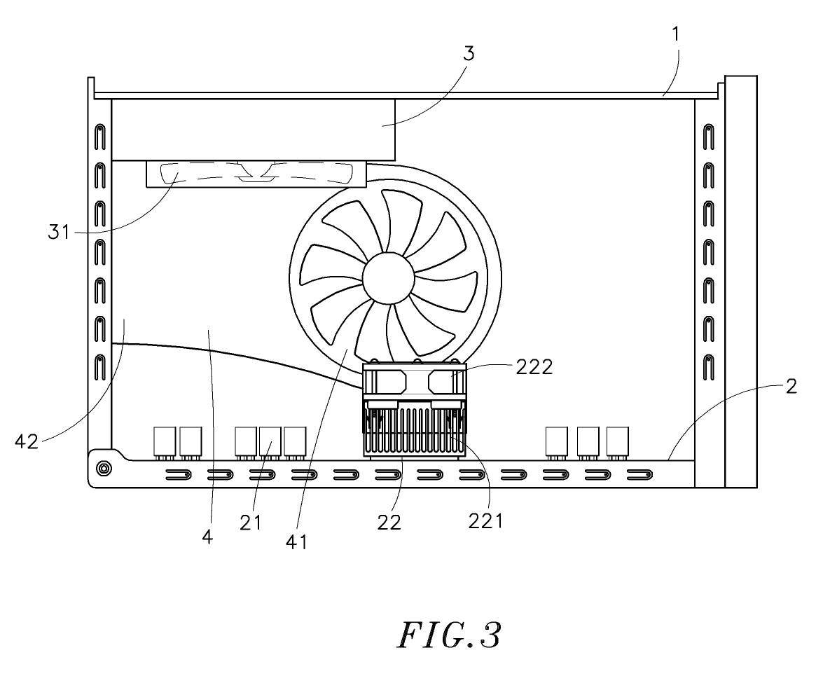

FIG. 1 is an elevational view of a computer case comprising a heat sink device according to an embodiment of the present invention. FIG. 2 is an elevational view of the computer case comprising a heat sink device shown in FIG. 1 when viewed from another direction. FIG. 3 is a side view of the computer case comprising a heat sink device shown in FIG. 1. Referring to FIGS. 1, 2, and 3, the computer case comprising a heat sink device, according to an embodiment of the present invention, comprises a computer case 1, a motherboard 2, a power supplier 3 and a scroll fan 4. A plurality of ventilation holes 11 and a plurality of heat exhaust holes 12 are formed on a sidewall of the computer case 1. The motherboard 2 is installed on an inner bottom side of the computer case 1. The motherboard 2 comprises a plurality of electronic components 21, a CPU 22 having a plurality of heat exchange plates 221 thereon and a heat exchange fan 222. The power supplier 3 having a heat exchange fan 31 is installed above the motherboard 2 with a side thereof attached to an inner side of the heat exhaust holes 12 of the computer case 1. Additionally, the scroll fan 4 is installed below the power supplier 3 vertically positioned relative to the motherboard 2. The scroll fan 4 comprises an air inlet 41 and an air outlet 42 for providing mass air exhaust capability. The air outlet 42 is positioned on an inner side of the ventilation holes 11 formed on the sidewall of the computer case 1. The air inlet 41 of the scroll fan 4 is vertically positioned relative to the side of the motherboard 2. Thus, the air inlet 41 of the scroll fan 4 is adapted for circulating air generated by the operation by the scroll fan 4 on the motherboard 2 for dissipating the heat from the motherboard 2 and exhausting the air out of the computer case 1. Furthermore, the heat generated by the power supplier 3 can be directly exhausted through the heat exhaust holes 12. Therefore, the heat from inside the computer case 1 can be effectively dissipated out.

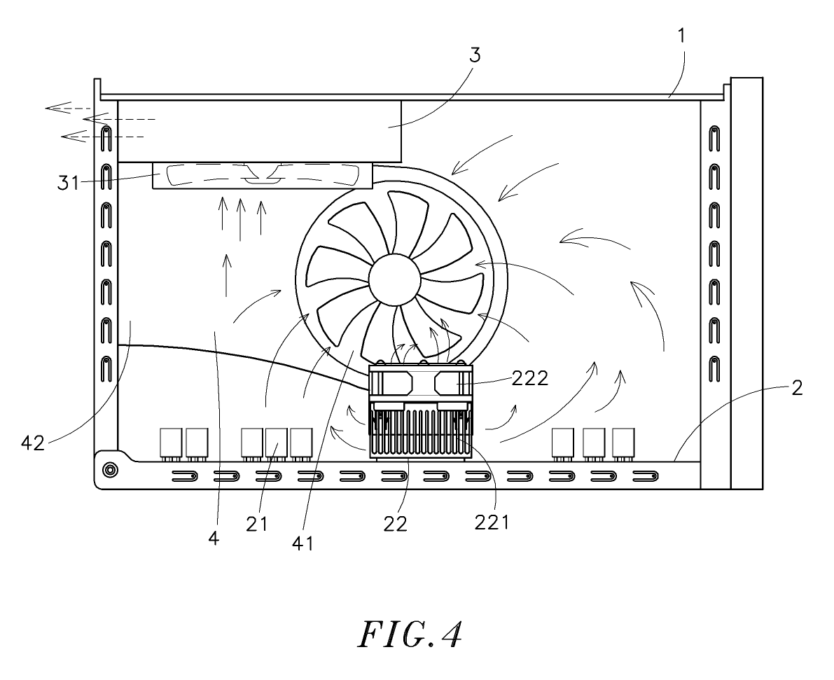

Hereinafter, the operation of the heat sink device according to an embodiment of the present invention will be described with reference to FIGS. 3 and 4. Wherein, FIG. 3 is a side view of the computer case comprising a heat sink device shown in FIG. 1. FIG. 4 is a view showing an operation of the scroll fan according to an embodiment of the present invention. The operation of various electronic components 21, the CPU 22 and the power supplier 3 on the motherboard 2 installed within the computer case 1 generate heat. The operation of scroll fan 4 generates air, which is circulated within the computer case 1 to dissipate the heat from inside the computer case 1 through the air outlet 42 to outside. Due to the mass heat exhaustion is larger than the mass heat absorption by the operation of the scroll fan 4, so the excellent air circulation is provided to cover a larger area, and therefore heat absorption and heat dissipation can be effectively improved. Therefore, the heat within the computer case 1 can be effectively dissipated out of the computer case 1 and mixes with the outside cooler air. The air circulation within the computer case 1 provided by the operation of the scroll fan 4 can greatly improve the dissipation of heat generated by the electronic components 21, the CPU 22 and the power supplier 3. The heat generated by the operation power supplier 3 can be directly exhausted through the heat exhaust holes 12. Thus, the heat generated by the operation of the electronic components 21, the CPU 22 and the power supplier 3, and the like, can be effectively dissipated out of the computer case 1, and accordingly the service life of the electronic components can be effectively extended.

The heat sink device of a computer case according to an embodiment of the present invention has at least the following advantages.

1. The air generated by the operation of scroll fan 4 provide better air circulation effect and cover larger area on the mother board 2 and thereby provide a larger heat absorption area, and therefore the heat dissipation from the computer case 1 can be effectively improved.

2. The speed of the heat dissipation can be greatly improved by the scroll fan 4, therefore the heat generated by the electronic components 21, CPU 22 and the power supplier 3 can be efficiently and effectively dissipated.

3. The ventilation holes 11 in conjunction with the air outlet 42 of the scroll fan 4 promote heat exchange, and the heat generated by the operation of the power supplier 3 can be dissipated through the plurality of heat exhaust holes 12. Therefore, the heat can be effectively removed from the computer case 1.

4. The heat from within the computer case 1 can be easily removed through the large size heat inlet 41 of the scroll fan 4, and also the air circulation generated by the operation of the scroll fan 4 can aid to air circulation to exhaust the heat from inside the computer case 1 to outside thereby dissipating heat from the computer case 1.

5. The cool air generated by the operation of the scroll fan 4 exchanges heat within the computer case 1 which is then exhausted out of the computer case 1.

6. The scroll fan 4 is installed vertical relative to the motherboard 2, the cool air generated during operating the scroll fan 4 circulates on the motherboard 2 and which in turn absorbs the heat from the motherboard 2, thus the heat generated by the operation of the electronic components 21, the CPU 22 and the power supplier 3 can be efficiently exchanged with the cool air within the computer case 1 and dissipated out. Therefore, the heat is effectively dissipated out of the computer case 1.

While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations in which fall within the spirit and scope of the included claims. All matters set forth herein or shown in the accompanying drawings are to be interpreted in an illustrative and nonlimiting sense.

1. A heat sink device of a computer case, said computer case comprising at least a plurality of ventilation holes and a plurality of exhaust holes formed on a sidewall thereof, wherein at least a motherboard and a power supplier are installed within said computer case, the heat sink device comprising:
a scroll fan, installed inside said computer case below said power supplier, wherein said scroll fan comprises:
an air inlet, at a distal end thereof;
an air outlet, at a primal end thereof, wherein said air outlet is connected to said ventilation holes of said computer case; and
wherein said scroll fan is adapted for generating air and circulating air within said computer case, and dissipating heat from inside said computer case.

2. The heat sink device of a computer case accordingly to claim 1, wherein said ventilation holes are larger compared to said exhaust holes.

3. The heat sink device of a computer case accordingly to claim 1, wherein said scroll fan adapted for generating air for exchanging heat within said computer case and dissipating heat out of said computer case such that a mass heat exhaustion is larger than a mass heat absorption.
